(19) United States
(12) Patent Application Publication
(10) Pub. No.: US 2009/0227110 A1
(43) Pub. Date: Sep. 10, 2009

(54) Method of Forming Mask Pattern

(75) Inventor: Joo Won HWANG, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/147,205

(22) Filed: Jun. 26, 2008

(30) Foreign Application Priority Data
Mar. 10, 2008 (KR) 2008-21936

(51) Int. Cl. H01L 21/311

(52) U.S. Cl. 438/694; 257/E21.249

(57) ABSTRACT

A method of forming a mask pattern provides a resolution below a resolution of a conventional exposure equipment. The method may include a self-align double etching process in which a nipple formed by hard mask layers having different etching selection ratios is utilized, and a micro pattern to be practically obtained is formed by means of the mask pattern. Using conventional exposure equipment, a micro pattern may have a width below a resolution of the conventional exposure equipment.

### CROSS-REFERENCE TO RELATED APPLICATIONS

This application claims priority from Korean Patent Application No. 2008-0021936, filed on Mar. 10, 2008, the contents of which are incorporated herein by reference in its entirety.

### BACKGROUND OF THE INVENTION

The present invention relates to a method of forming a mask pattern, more particularly the present invention relates to a method of forming a mask pattern capable of overcoming a resolution of an exposure equipment to form a micro pattern having a width below a resolution of the exposure equipment.

Semiconductor devices are becoming smaller and highly-integrated enhancing existing and offering the potential for new functions of the semiconductor device. The patterning technology to make such small, highly integrated semiconductor devices is a concern. The current patterning technology, including photolithography process, is capable of embodying a high-integrity semiconductor and has been developed as a core technology in the semiconductor manufacturing process. Photolithography is the mainly utilized patterning process. In a photolithography process, a light responsive chemical substance is applied to form a photoresist layer, an exposure process and a developing process are performed for the photoresist layer to form a mask pattern. Then, an underlying layer is selectively etched by using the formed mask pattern to pattern the underlying layer.

A resolution of current exposure equipment is 46 nm on the basis of a half pitch. Exposure equipment for forming a pattern having a resolution beyond the processing capability limitation of conventional exposure equipment is highly desirable, but such equipment remains under development and is expensive. A method being capable of defining a reduced size cell by means of a conventional exposure equipment is sincerely desired.

In order to realize the above purpose, a double photo method is an alternative proposal. However, this method has a serious problem in that uniformity of the critical dimension (CD) becomes lowered due to mis-alignment caused by a lack of an overlay margin.

### SUMMARY OF THE INVENTION

It is a feature of the present invention to provide a method of forming a mask pattern using conventional exposure equipment to form a micro pattern having a width below a resolution of the conventional exposure equipment.

The method of forming a mask pattern according to one embodiment of the present invention may include forming sequentially an etching-target layer, a first hard mask layer and a second hard mask layer on a semiconductor substrate; patterning the first and second hard mask layers to form first and second hard mask patterns having a first width; etching the second hard mask layer pattern to allow the second hard mask layer pattern to remain on a center of the first hard mask layer pattern, the etched second hard mask layer pattern having a second width smaller than the first width; filling a space between the second hard mask layer patterns having the second width and a space between the first hard mask layer patterns with a third hard mask layer; removing the second hard mask layer patterns; etching the exposed first hard mask layer pattern between the third hard mask layers; and removing the third hard mask layers to form the first hard mask layer patterns, each of the first hard mask layer patterns having a third width.

In the method, the first hard mask layer patterns having the first width may be formed such that a sum of the first width of the first hard mask layer pattern and a width of a space between the first hard mask layer patterns is twice the target pattern pitch.

The second hard mask pattern layer having the second width may be formed such that the second width the second hard mask pattern layer is the same as that of the space between the first hard mask layer patterns having the first width.

The second hard mask layer pattern having the second width may be formed by etching the second hard mask layer pattern having the first width through an isotropic etching process. The isotropic etching process may be performed by using diluted hydrofluoric solution having a volume ratio between hydrofluoric acid and water (HF:H20) of 1:50 to 1:200.

The isotropic etching process may be performed such that both edge portions of the second hard mask layer pattern having the first width are etched by a width of the space formed between the first hard mask layer patterns having the first width, whereby the second hard mask layer pattern having the second width is remained in the shape of a nipple.

The isotropic etching process may be performed such that a vertical portion of the second hard mask layer pattern having the first width is etched along with the second hard mask layer pattern, whereby a height of the second hard mask layer pattern having the second width is at least half or more of a height of the second hard mask layer pattern having the first width.

The first and second hard mask layers may be made from materials having etching selection ratios which differ from each other. The second hard mask layer may be formed of an oxide layer. In addition, the first hard mask layer may be formed of a nitride layer.

The third hard mask layer may be made from material having an etching selection ratio which differs from those of the first and second hard mask layers, and the third hard mask layer may be formed of a polysilicon layer.

### BRIEF DESCRIPTION OF THE DRAWINGS

The above and other features and advantages of the present invention will become readily apparent by reference to the following detailed description when considered in conjunction with the accompanying drawings wherein:

FIG. 1A to FIG. 1I are sectional views of a semiconductor device for illustrating a method of forming a mask pattern according to various embodiments of the present invention.

### DESCRIPTION OF SPECIFIC EMBODIMENTS

Hereinafter, the specific embodiments of the present invention will be explained in more detail with reference to the accompanying drawings. However, it should be understood that the present invention is not limited to the embodiments described below and the embodiments of the present invention can be variously modified. The scope of the present invention is not limited to the embodiments described herein, and the embodiments are provided for explaining more completely the present invention to those skilled in the art.

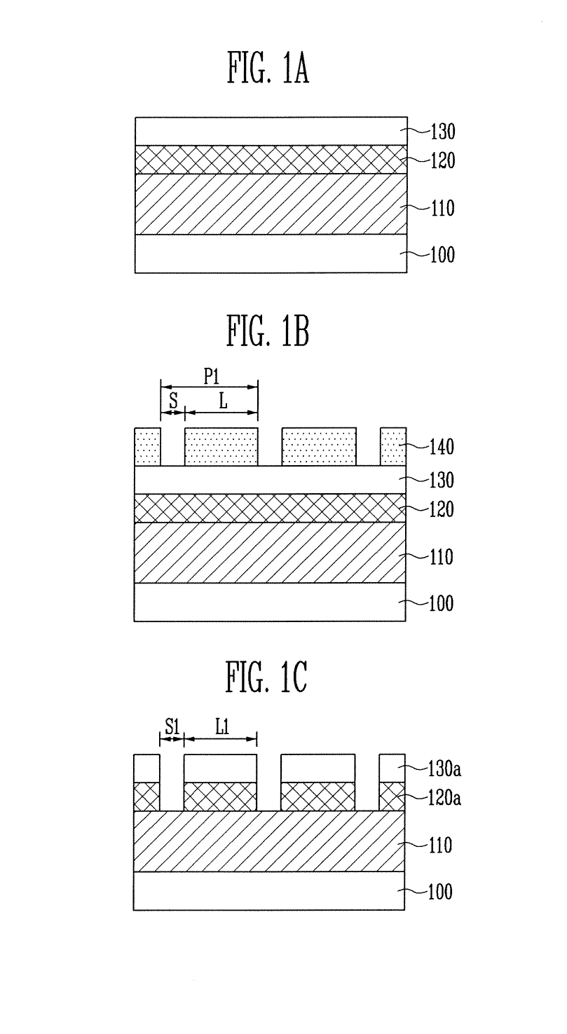

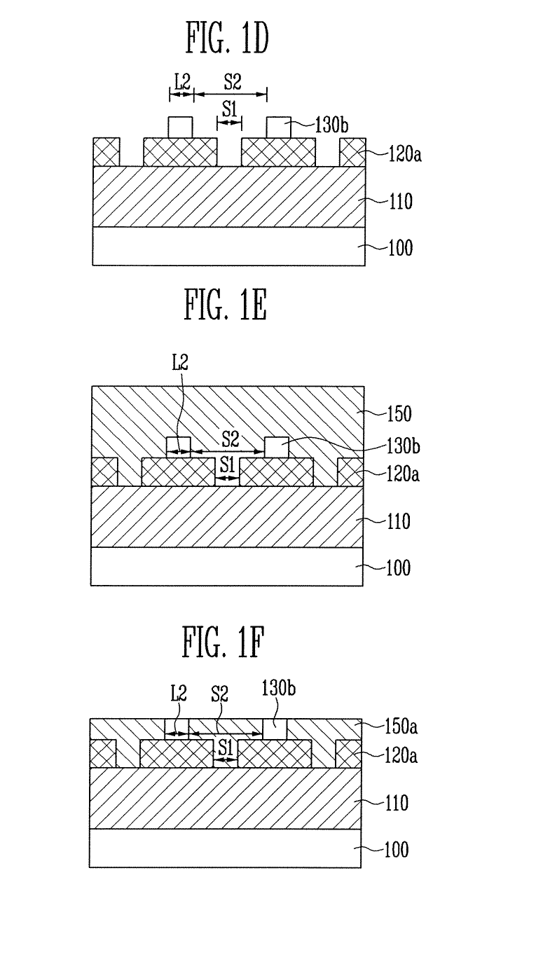

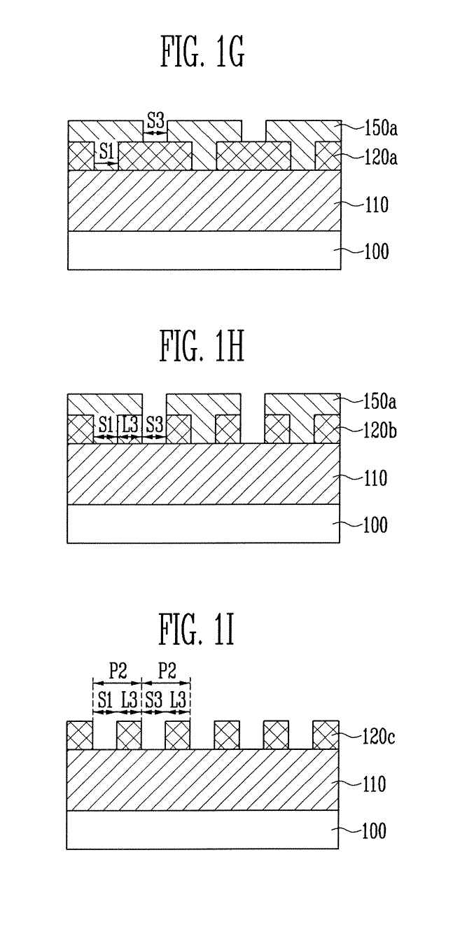

FIG. 1A to FIG. 1I are sectional views of a semiconductor device for illustrating a method of forming a mask pattern according to various embodiments of the present invention.

Referring to FIG. 1A, first and second hard mask layers 120 and 130 having etching selection ratios that differ from each other are sequentially formed on a semiconductor substrate 100 on which an etching-target layer 110 is formed. The etching-target layer 110 is the objective layer on which a micro pattern will be actually formed, and material used for forming the etching-target layer is determined according to a purpose of the etching-target layer. For example, in a case where the micro pattern is formed of a metal wire, the etching-target layer 110 can be formed of a metal layer, and in a case where the micro pattern is formed from an isolation layer, the etching-target layer 110 can be formed of an insulating layer (i.e., an oxide layer).

On the other hand, the first hard mask layer 120 may have an etching selection ratio that differs from that of the second hard mask layer 130. At this time, in order to perform a subsequent isotropic etching process in which the second hard mask layer 130 is etched in every direction at a similar ratio through solution containing hydrofluoric acid, the second hard mask layer 130 is formed of an oxide layer, and the first hard mask layer 120 may be formed of a nitride layer.

Referring to FIG. 1B, photoresist layer patterns 140 are formed on the second hard mask layer 130. Photo sensitive material (for example, photoresist) is applied on the second hard mask layer 130 to form a photoresist layer, and the photoresist layer is then patterned through an exposure process and a developing process to form the photoresist layer patterns 140.

At this time, the photoresist layer can be patterned by using an exposure equipment having a resolution of 46 nm to 200 nm to form the photoresist layer patterns 140. By the above patterning process, a pattern pitch P1 defined as a sum of a width L of the photoresist layer pattern 140 and a width S of a space formed between the photoresist layer patterns 140 is defined. At this time, the photoresist layer patterns 140 are formed such that the pattern pitch P1 is wider than two times a target pattern pitch to be actually obtained. In general, a limitation (resolution) of process capability of an exposure equipment is represented on the basis of a half pitch that is a half of the pattern pitch defined as a sum of a line pattern and a space.

Referring to FIG. 1C, the second and first hard mask layers (130 and 120 in FIG. 1B) are sequentially patterned by means of the photoresist layer patterns (140 in FIG. 1B) as a mask. At this time, a dry etching process is performed as the patterning process. As a result, first and second hard mask layer patterns 120a and 130a having a first width L1 are formed, and a space with a first width S1 is formed between stack layers consisting of the first and second hard mask layer patterns 120a and 130a. In addition, the etching-target layer 110 is exposed through the above space. In other words, the first and second hard mask layer patterns 120a and 130a are patterned by means of an exposure equipment having a resolution of 46 to 200 nm. Then, the photoresist layer patterns (140 in FIG. 1B) are removed.

Referring to FIG. 1D, an etching process for the second hard mask layer (130a in FIG. 1C) is performed to form a second hard mask layer pattern 130b on a central portion of the first hard mask layer pattern 120a, the second hard mask layer pattern 130b having a second width L2 less than the first width L1. Preferably, the etching process is performed such that the second hard mask layer pattern 130b is formed on a central portion of the first hard mask layer pattern 120a and has the second width L2 which is the same as the first width S1 of the space between the first hard mask layer patterns 120a.

To form the second hard mask layer pattern 130b, an isotropic etching process in which the second hard mask layer pattern (130a in FIG. 1C) having the first width L1 is etched in every direction at a similar ratio is performed. Preferably, a wet etching process can be performed as the isotropic etching process. In this case, diluted hydrofluoric (DHF) solution having a volume ratio between hydrofluoric acid and water (HF:H20) of 1:50 to 1:200, preferably, a volume ratio between hydrofluoric acid and water (HF:H20) of 1:100 can be used in the wet etching process.

As a result, both edge portions of the second hard mask layer pattern (130a in FIG. 1C) are etched by a certain width through the isotropic etching process, and so a second hard mask layer pattern 130b in the shape of a nipple remains on a central portion of the first hard mask layer pattern 120a. The second hard mask layer pattern 130b having a width that is the same as the first width S1 of the space is formed between the first hard mask layer patterns 120a. In this case, a space having a second width S2, which is larger than three times the first width S1 of the space, is formed between the second hard mask layer patterns 130b having the nipple shape.

On the other hand, when the isotropic etching process is performed, a vertical portion of the second hard mask layer pattern (130a in FIG. 1C) is etched by a certain thickness, and so the second hard mask layer pattern 130b having the second width L2 has a height which is at least a half or more of a height of the second hard mask layer pattern (130a in FIG. 1C) having the first width L1.

Referring to FIG. 1E, a third hard mask layer 150 is formed on the etching-target layer 110 including the first and second hard mask layer patterns 120a and 130b to fill a space between the first mask layer patterns 120a and a space between the second hard mask layer patterns 130b. The third hard mask layer 150 is formed from material having an etching selection ratio that differs from those of the first hard mask layer pattern 120a and the second hard mask layer pattern 130b (or the first and second hard mask layers (120 and 130 in FIG. 1A)). Preferably, the third hard mask layer may be formed of polysilicon.

Referring to FIG. 1F, a planarizing process, for example, a chemical mechanical polishing process is performed until a surface of the second hard mask layer pattern 130b is exposed. As a result, a third hard mask layer pattern 150a in the shape of “T” is formed between the first and second hard mask layer patterns 120a and 130b.

Referring to FIG. 1G, an etching process is performed for removing selectively the exposed second hard mask layer pattern (130b in FIG. 1F) between the third mask layer patterns 150a. As the above etching process, a dry etching process may be performed. In the above etching process, an etching recipe having a higher etching ratio with respect to the second hard mask layer pattern (130b in FIG. 1F), rather than the third hard mask layer pattern 150a, is utilized.

According to an embodiment of the present invention, since the second hard mask layer pattern (130b in FIG. 1F) is formed from an oxide layer and third hard mask layer pattern 150a is formed from a polysilicon layer, the etching process for removing selectively the exposed second hard mask layer pattern (130b in FIG. 1F) is performed by using an etching recipe having a higher etching selection ratio with respect to the oxide layer, rather than the polysilicon layer.

Consequently, the exposed second hard mask layer pattern (130b in FIG. 1F) is selectively removed, and so a portion of the surface of the first hard mask layer pattern 120a is exposed by the second width L2 and a space having a third width S3 which is the same as the second width L2 is formed between the third hard mask layer patterns 150a. Preferably, the second hard mask layer pattern (130b in FIG. 1F) is removed by a self-align double etching manner.

Referring to FIG. 1H, an etching process is performed for removing selectively the exposed first hard mask layer pattern (120a in FIG. 1G). As the above etching process, a dry etching process may be performed. In this case, the above etching process is performed by using an etching recipe having a higher etching selection ratio with respect to the first hard mask layer pattern 120a, rather than with respect to the third hard mask layer pattern 150a.

According to an embodiment of the present invention, since the first hard mask layer pattern (120a in FIG. 1G) is formed from a nitride layer and the third hard mask layer pattern 150a is formed from a polysilicon layer, the etching process for removing selectively the exposed first hard mask layer pattern (120a in FIG. 1G) is performed by using an etching recipe having a higher etching selection ratio with respect to the nitride layer, rather than with respect to the polysilicon layer

As a result, a portion of a surface of the etching-target layer 110 corresponding to a removed portion of the exposed first hard mask layer pattern (120a in FIG. 1G) is exposed by the third width S3 and first hard mask layer patterns 120b having the third width L3 are formed below both edges of the third hard mask layer pattern 150a. At this time, the third width S3 may be the same as the first width S1. In this case, the spaces having the first and third width S1 and S3 and the first hard mask pattern 120b having the third width L3 become the same in width.

Referring to FIG. 1I, an etching process is carried out for removing the third hard mask layer pattern (150a in FIG. 1H). As the above etching process, a dry etching process may be performed. In this case, the above etching process is performed by using an etching recipe having a higher etching selection ratio with respect to the third hard mask layer pattern (150a in FIG. 1H), rather than with respect to the first hard mask layer pattern (120a in FIG. 1H) and the etching-target layer 110.

According to an embodiment of the present invention, since the first hard mask layer pattern (120b in FIG. 1H) is formed from a nitride layer, the etching-target layer 110 is formed of a metal layer or an oxide layer and the third hard mask layer pattern (150a in FIG. 1H) is formed from a polysilicon layer, the etching process for removing selectively the third hard mask layer pattern (150a in FIG. 1H) is performed by using an etching recipe having a higher etching selection ratio with respect to the nitride layer, the metal layer and the oxide layer, rather than with respect to the polysilicon layer

As described above, since the third mask layer pattern (150a in FIG. 1H) is selectively removed, the first hard mask layer pattern (120b in FIG. 1H) having the third width L3 remaines on the etching-target 110, this remaining first hard mask layer pattern is formed as a target mask pattern 120c. At this time, spaces having the first width S1 and spaces having the third width S3 are alternatively disposed, each of which being disposed between the target mask patterns 120c.

Here, since the first width S1 of the space is the same as the third width S3 of the space, a sum of the first width S1 of the space and the third width L3 of the target mask pattern 120c or a sum of the third width S3 of the space and the third width L3 of the target mask pattern 120c is defined as a target pattern pitch P2. Accordingly, the target mask patterns 120c having the same target pattern pitch P2 are formed on the etching-target layer 110. At this time, the target pattern pitch P2 is a half of the pattern pitch P1.

According to embodiments of the present invention as herein described, in a case where the target mask pattern 120c is formed through the self-align double etching process in which the nipple formed by the first and second hard mask layers 120 and 130 having the different etching selection ratios is utilized, it is possible to embody the pattern pitch corresponding to a half of the resolution of a conventional exposure equipment. It means that, although a conventional exposure equipment is utilized, it is possible to form the target mask pattern 120c having a width below the resolution of a conventional exposure equipment, that is, having a width of 46 nm or below.

Since the target mask pattern 120c formed as described in connection with the various embodiments of the invention is utilized as the mask for forming the pattern to be actually embodied in the process for fabricating a semiconductor device, if the etching-target layer 110 is etched by means of the target mask pattern 120c in a subsequent process, it is possible to form practically the micro pattern having a width of 46 nm or below through a conventional exposure equipment having a resolution of 46 nm to 200 nm. The above method of forming the mask pattern can be applied to a process for forming a micro pattern such as a gate, an isolation layer and a metal wire.

The method of forming the mask pattern according to the present invention utilizes a conventional exposure equipment to form a micro pattern having a width below a resolution of a conventional exposure equipment, and so the present invention can save the investment cost for a novel exposure equipment. In addition, the method of the present invention can secure an overlay margin to secure stably the uniformity of the CD (critical dimension).

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming a mask pattern, comprising the steps of:
forming sequentially an etching-target layer, a first hard mask layer and a second hard mask layer on a semiconductor substrate;
patterning the first and second hard mask layers to form first and second hard mask layer patterns each having a first width;
etching the second hard mask layer patterns to allow the second hard mask layer patterns to remain on a center of the first hard mask layer patterns, the etched second hard mask layer patterns having a second width smaller than the first width;
filling a space between the etched second hard mask layer patterns and a space between the first hard mask layer patterns with a third hard mask layer;
removing the etched second hard mask layer patterns exposing the first hard mask layer patterns between the third hard mask layer;
etching the exposed first hard mask layer patterns between the third hard mask layer; and
removing the third hard mask layer to form the first hard mask layer patterns having a third width.

2. The method of forming a mask pattern of claim 1, wherein the first hard mask layer patterns having the first width are formed such that a sum of the first width and a width of a space between the first hard mask layer patterns is twice the target pattern pitch.

3. The method of forming a mask pattern of claim 1, wherein the etched second hard mask layer patterns having the second width are formed such that the second width is the same as that of the space between the first hard mask layer patterns having the first width.

4. The method of forming a mask pattern of claim 1, wherein the second hard mask layer patterns having the second width are formed by etching the second hard mask layer patterns having the first width through an isotropic etching process.

5. The method of forming a mask pattern of claim 4, wherein the isotropic etching process is performed by using diluted hydrofluoric solution having a volume ratio between hydrofluoric acid and water (HF:H20) of 1:50 to 1:200.

6. The method of forming a mask pattern of claim 5, wherein the isotropic etching process is performed such that both edge portions of the second hard mask layer patterns having the first width are etched by a width of the space formed between the first hard mask layer patterns having the first width, whereby the second hard mask layer patterns having the second width remains in the shape of a nipple.

7. The method of forming a mask pattern of claim 5, wherein the isotropic etching process is performed such that a vertical portion of the second hard mask layer patterns having the first width is etched along with the second hard mask layer patterns such that a height of the second hard mask layer patterns having the second width is at least half or more of a height of the second hard mask layer patterns having the first width.

8. The method of forming a mask pattern of claim 1, wherein the first and second hard mask layers are made from materials having etching selection ratios which differ from each other.

9. The method of forming a mask pattern of claim 8, wherein the second hard mask layer is formed of an oxide layer.

10. The method of forming a mask pattern of claim 8, wherein the first hard mask layer is formed of a nitride layer.

11. The method of forming a mask pattern of claim 1, wherein the third hard mask layer is made from material having an etching selection ratio different than that of each of the first and second hard mask layers.

12. The method of forming a mask pattern of claim 11, wherein the third hard mask layer is formed of a polysilicon layer.
